(19) United States
(12) Patent Application Publication
(10) Pub. No.: US 2023/0031411 A1
(43) Pub. Date: Feb. 2, 2023

(54) High-Aspect-Ratio Glass Capillary Array and a Method for Conformally Metal-Coating Same

(71) Applicant: GOVENMENT OF UNITED STATES OF AMERICA AS REPRESENTED BY THE SECRETARY OF THE NAVY, ARLINGTON, VA (US)

(72) Inventors: Marc Christophersen, Berwyn Heights, MD (US); Bermard F. Phlips, Great Falls, VA (US)

(21) Appl. No.: 17/825,100

(22) Filed: May 26, 2022

Related U.S. Application Data
(60) Provisional application No. 63/227,357, filed on Jul. 30, 2021.

(51) Int. Cl. C03B 37/14; B01L 3/00; B01J 23/755; C23C 30/00; B01J 23/72

(52) U.S. Cl. CPC C03B 37/14; B01L 3/00; B01J 23/755; C23C 30/005; B01J 23/72; B01L 2300/0838

(57) ABSTRACT

A conformally metal-coated glass capillary array and method of fabricating same. A glass capillary array is provided. The glass capillary array includes a plurality of glass capillaries. The glass capillary array includes a plurality of glass capillary array walls. The plurality of glass capillary array walls define a plurality of holes. The plurality of holes includes a plurality of hole peripheries. An electroless metallization catalyst is provided around the plurality of hole peripheries. A first metal is electroless plated on the plurality of glass capillary array walls using the electroless metallization catalyst. A second metal is electroplated on the electroless-plated, first metal, or the second metal is electroless-plated on the electroless-plated, first metal.

### CROSS-REFERENCE TO RELATED APPLICATIONS

This Application claims the benefit of U.S. Provisional Application Ser. No. 63/227,357 filed on 30 Jul. 2021, the entirety of which is incorporated herein by reference.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; techtran@nrl.navy.mil, referencing NC 210614-US2.

### BACKGROUND OF THE INVENTION

### Field of the Invention

This invention relates in general to a glass capillary array and method of manufacturing same, and in particular to a conformally metal-coated glass capillary array and method of manufacturing same.

### Description of the Related Art

Glass Capillary Arrays (“GCAs”) include millions of precision glass capillary tubes fused together to produce a uniform and mechanically rigid structure. A common use is in night vision equipment as so-called Micro-Channel-Plates (“MCPs”). MCPs are essentially fast, high-gain amplifiers for electrons using the parallel spatial channels for imaging applications. They can be also used for sample filtration, collimation or as optical beam line splitters. They can be made into custom sizes and shapes.

Metal-coated GCAs can be used as collimators for X-ray astronomy instrumentations.

For example, the Spectroscopic Time-Resolving Observatory for Broadband Energy X-rays (“STROBE-X”) would benefit from metal-coated GCAs. Furthermore, metal-coated GCAs can improve medical X-ray imaging systems. X-Ray collimators based on GCAs are composed of glass capillaries in a dense array. It is a known technology capable of producing large areas with high aspect-ratio holes; however, the choice of glass for the collimator material has some drawbacks. These collimator perform poorly at energies above>10 keV.

### SUMMARY OF THE INVENTION

An embodiment of the invention includes a method of fabricating a conformally metal-coated glass capillary array. The method includes providing a glass capillary array. The glass capillary array includes a plurality of glass capillaries. The glass capillary array includes a plurality of glass capillary array walls. The plurality of glass capillary array walls define a plurality of holes. The plurality of holes includes a plurality of hole peripheries. The method includes providing a standard electroless metallization catalyst around the plurality of hole peripheries. The method includes electroless plating a standard first metal on the plurality of glass capillary array walls using the electroless metallization catalyst. The method includes electroplating a standard second metal on the electroless-plated, first metal, or electroless plating the second metal on the electroless-plated, first metal.

Another embodiment of the instant invention includes a glass capillary array. The glass capillary array includes a plurality of glass capillary array walls. The plurality of glass capillary array walls define a plurality of holes. The plurality of holes includes a plurality of hole peripheries. The glass capillary array includes an electroless metallization catalyst on the plurality of glass capillary array walls around the plurality of hole peripheries. The glass capillary array includes an electroless-plated first metal on the electroless metallization catalyst. The glass capillary array includes an electroplated second metal on the electroless-plated first metal or an electroless-plated second metal on the electroless-plated first metal.

Another embodiment of the instant invention includes a fabrication sequence. The fabrication sequence includes a three step process: (i) coating of a GCA's array walls by metal ALD (atomic layer deposition), (ii) electroless nickel deposition for thicker conducting layer, and (iii) metal (e.g., gold and/or copper) electroplating. For example, a homogenous platinum coating is developed by atomic layer deposition (“ALD”). Because ALD is an inherently slow process, depositing thick-conducting films is extremely time-consuming. However, electroplating requires a good conducting film. A 200 nm thick highly conducting film can be plated within, for example, 20 min. Nickel is used as a starting layer for gold or copper electroplating. Platinum ALD acting as a starting catalyst for the electroless nickel then enables to possibility of electroplating various thick metal coatings. Copper and gold films are electroplated onto the nickel, conformally covering the GCA's array walls. The use of electroless plating Ni between the ALD deposition and the electroplating is a novel step. The Ni layer provides the good conducting layer for the electroplating step. Using the ALD alone to forma a thick enough conductor is not practical because the deposition is too slow and form mechanically stressed films.

In an embodiment of the instant invention, substantially reduced on-axis transparency of the GCA collimator above 10 keV eliminates contamination by bright and/or variable X-ray sources outside, but still close to, the nominal STROBE-X field of view.

For 10 keV, the effect of a conformal gold coating according to an embodiment of the instant invention becomes significant. For example, ten microns of conformal gold coating enable a one-degree field of view. Micron-thick layers cannot be fabricated by ALD alone; however, the combination of an ALD seed layer and electroplating according to an embodiment of the instant invention, can produce micron-thick films inside a GCA.

In an embodiment of the instant invention, use of electroless nickel circumvents an expansive and time-consuming metal ALD deposition as a starting layer for the electroplating. The nickel deposition, for example, is done in a bath and scaled up easily.

In an embodiment of the instant invention, a silanization process completely circumvents the need for any ALD deposition, making the overall process much faster and cost effective.

In an embodiment of the instant invention, cycling electroless Ni, for example, via a room temperature metallization (“RTM”) process, and Immersion Gold are both done in a chemical bath. As compared to scaling up an electroplating process to larger sample sizes, which can be complicated due to large electrolyte volumes and needed electrical currents, a standard bath process is scaled up much easier.

### BRIEF DESCRIPTION OF THE DRAWINGS

FIG. 1 is an illustrative glass capillary array according to an embodiment of the invention.

FIG. 2 is an illustrative conformally metal-coated glass capillary array according to an embodiment of the invention.

FIG. 3 is an illustrative conformally metal-coated glass capillary array according to another embodiment of the invention.

FIG. 4 is an illustrative conformally metal-coated glass capillary array according to another embodiment of the invention.

### DETAILED DESCRIPTION OF THE INVENTION

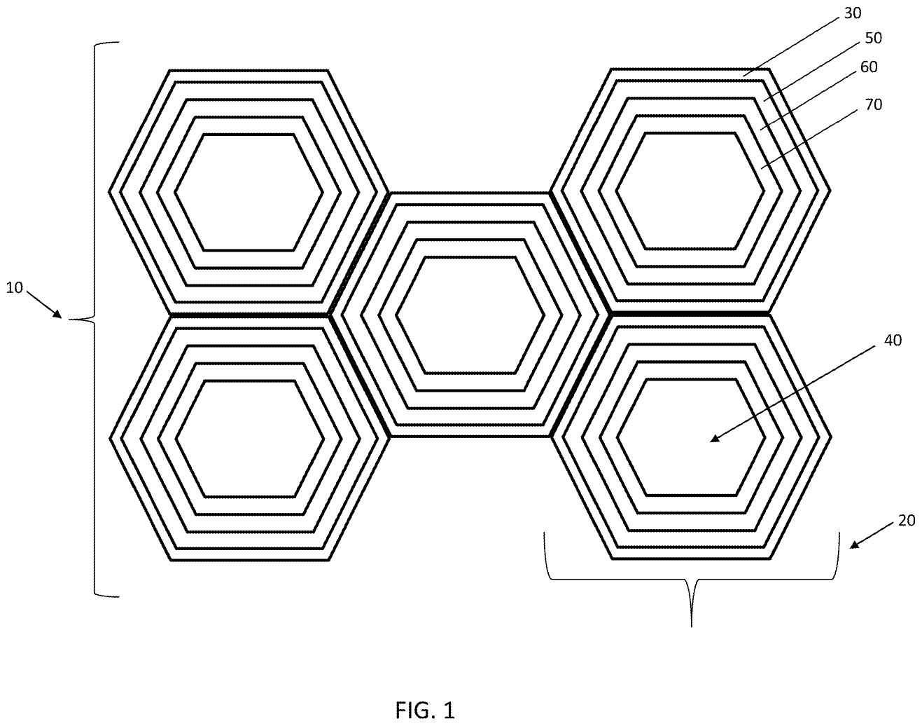

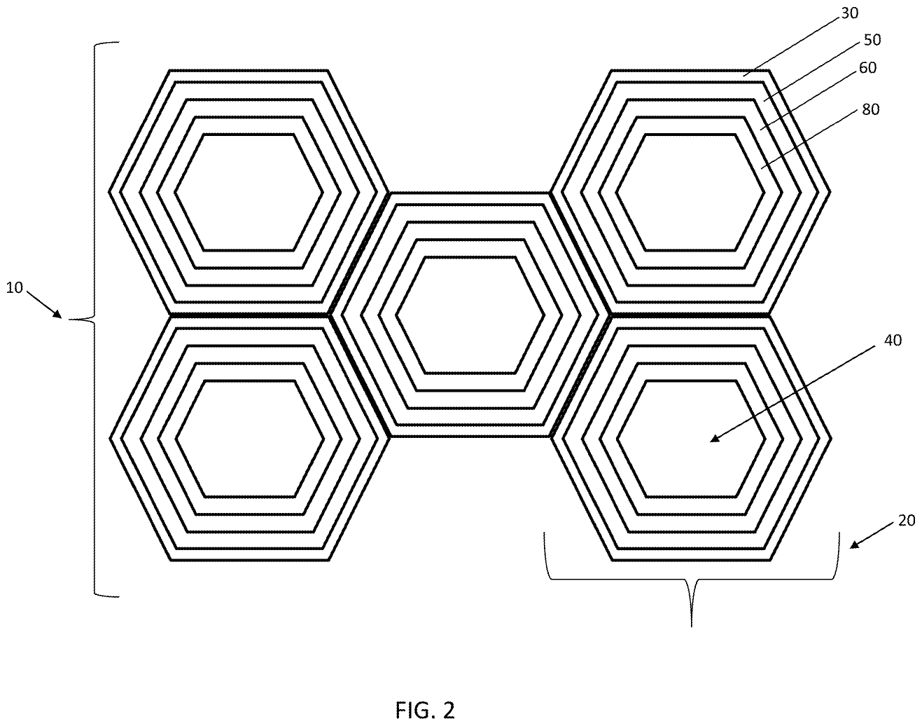

An embodiment of the invention includes a method of fabricating a conformally metal-coated glass capillary array. The method includes providing a standard glass capillary array 10, such as shown by way of illustration in FIGS. 1-4. One of ordinary skill in the art will readily appreciate that FIGS. 1-4 are not drawn to scale and that dimensions and aspect ratios shown in FIGS. 1-4 are exaggerated for the reader's ease of understanding. The glass capillary array 10 includes a plurality of standard glass capillaries. One of ordinary skill in the art will readily appreciate that although a practical GCA according to an embodiment of the invention includes thousands, if not millions, of glass capillaries, for ease of understanding, only five of the plurality of glass capillaries are shown and only one glass capillary 20 is provided a reference numeral. The glass capillary array includes a plurality of glass capillary array walls. One of ordinary skill in the art will readily appreciate that each glass capillary includes a respective glass capillary array wall. For ease of understanding, only one glass capillary array wall 30 is provided a reference numeral. The plurality of glass capillary array walls define a plurality of holes. That is, each glass capillary defines a respective hole. For ease of understanding, only one hole 40 is provided a reference numeral. The plurality of holes includes a plurality of hole peripheries. The method includes providing a standard electroless metallization catalyst 50 around the plurality of hole peripheries. One of ordinary skill in the art will readily appreciate that the electroless metallization catalyst and the layers thereon discussed below do not entirely fill the holes, as that would defeat the purpose of the glass capillary array 10. The method includes electroless plating a standard first metal on the plurality of glass capillary array walls using the electroless metallization catalyst 50, thereby providing the electroless plated first metal 60. The method includes electroplating a standard second metal on the electroless-plated, first metal(, thereby providing an electroplated second metal 70 as shown in FIG. 1), or electroless plating the second metal on the electroless-plated, first metal(, thereby providing an electroless plated second metal 80 as shown in FIG. 2).

Optionally, the electroless metallization catalyst includes a nickel catalyst, and the first metal includes nickel. The electroless plating a first metal on the plurality of glass capillary array walls using the electroless metallization catalyst includes electroless nickel plating the plurality of glass capillary array walls using the nickel catalyst. For example, the plurality of array walls are coated with the nickel catalyst. For example, each hole includes a diameter greater 10 μm, and the nickel catalyst coating on the array wall interiors is less than 500 nm thick.

Optionally, the electroless metallization catalyst includes a copper catalyst, and the first metal includes copper. The electroless plating a first metal on the plurality of glass capillary array walls using the electroless metallization catalyst includes electroless copper plating the plurality of glass capillary array walls using the copper catalyst.

Optionally, each hole of the plurality of holes includes an aspect ratio greater than 40:1. For the purpose of this patent application, “aspect ratio” is a term of art and is defined as the ratio of capillary length to capillary diameter, for each capillary of the glass capillary array.

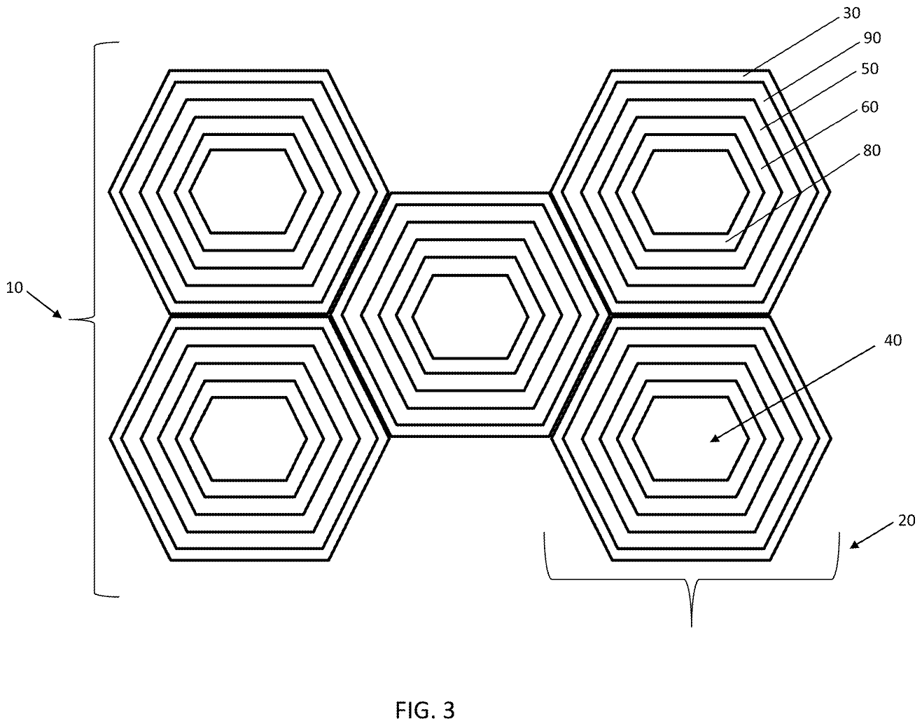

Optionally, the providing an electroless metallization catalyst around the plurality of hole peripheries includes coating the plurality of glass capillary array walls with a noble metal by atomic layer deposition. Optionally, such as shown by way of illustration in FIG. 3, the method further includes providing a wetting layer 90 on the plurality of array walls, prior to the coating the plurality of array walls with platinum by atomic layer deposition. In an alternative embodiment of the invention, the method further includes providing a wetting layer 90 on the plurality of array walls, prior to the coating the plurality of array walls with palladium by atomic layer deposition. For the purpose of this patent application, “wetting layer” is a term of art and is defined as a layer to improve adhesion between the glass capillary array walls and the platinum or platinum layer thereon. Optionally, the wetting layer 90 includes Al₂O₃ or TiO₂. The Al₂O₃ or TiO₂ layers can also deposited by ALD using standard ALD recipes. For example, even 20 to 50 ALD deposition cycles for TiO₂ provide an effective wetting layer. For example, the wetting layer 90 is on the order of nanometers thick.

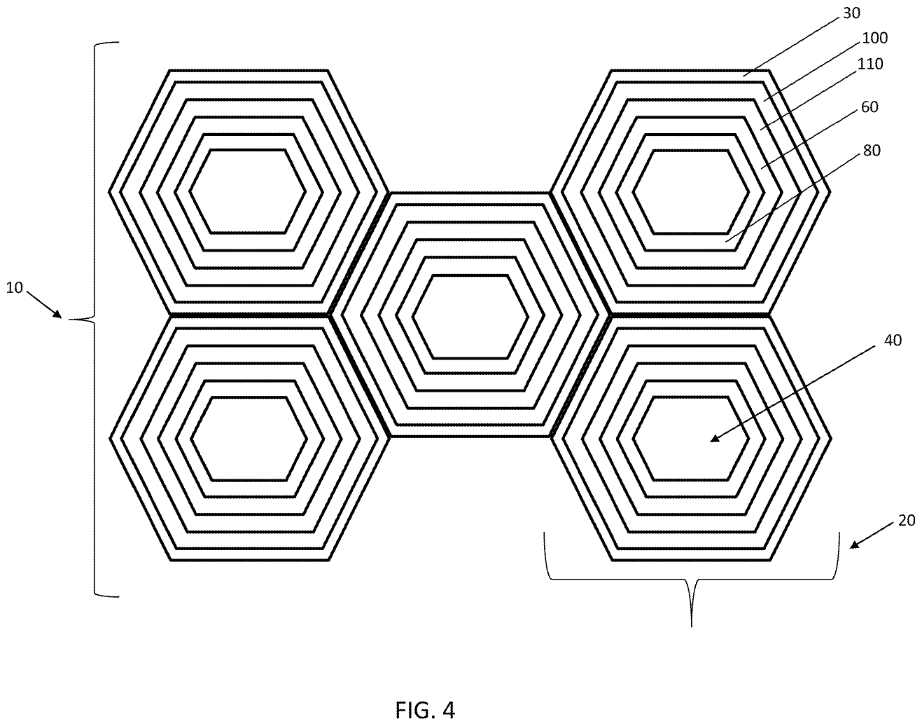

Optionally, the providing an electroless metallization catalyst on the plurality of hole peripheries includes the following. The plurality of glass capillary array walls are silanized, thereby providing a standard silane layer 100, such as shown by way of illustration in FIG. 4. Palladium(II) chloride is provided on the silanized plurality of glass capillary array walls, thereby providing a standard Palladium(II) chloride layer 110, such as shown by way of illustration in FIG. 4. One of ordinary skill in the art will readily appreciate that alternative palladium compounds are acceptable in alternative embodiments of the invention.

Optionally, the second metal includes a standard noble metal or a standard noble metal alloy. Optionally, the noble metal includes copper, gold, silver, or platinum. For example, in an embodiment of the invention, electroless noble metal plating includes, for example, electroless silver plating, electroless gold plating, electroless copper plating, or electroless platinum plating.

Another embodiment of the instant invention includes a glass capillary array 10. The glass capillary array 10 includes a plurality of glass capillary array walls. The plurality of glass capillary array walls define a plurality of holes. The plurality of holes includes a plurality of hole peripheries. The glass capillary array 10 includes an electroless metallization catalyst 50 on the plurality of glass capillary array walls around the plurality of hole peripheries. The glass capillary array 10 includes an electroless-plated first metal 60 on the electroless metallization catalyst 50. For example, the electroless-plated first metal 60 has a thickness on the order of a micron. The glass capillary array 10 includes an electroplated second metal 70 on the electroless-plated first metal 60 or an electroless-plated second metal 80 on the electroless-plated first metal 60. For example, the electroless-plated first metal 70 has a thickness on the order of a micron.

Optionally, the electroless metallization catalyst 50 includes a nickel catalyst, and the electroless-plated first metal 60 includes electroless-plated nickel. Optionally, the nickel catalyst includes platinum. Optionally, the nickel catalyst includes silane 100 and palladium 110 (e.g., Palladium(II) chloride).

Optionally, the electroless metallization catalyst includes a copper catalyst, and the electroless-plated first metal includes electroless-plated copper.

Optionally, the first metal includes a standard noble metal, and the second metal includes the noble metal or a noble metal alloy. Optionally, the noble metal includes copper, gold, silver, or platinum.

Optionally, each hole of the plurality of holes includes an aspect ratio greater than 40:1.

Optionally, the glass capillary array further includes a wetting layer 90 located between the plurality of glass capillary array walls and the electroless metallization catalyst 50. Optionally, the wetting layer 90 includes Al₂O₃ or TiO₂.

Another embodiment of the invention includes a method of fabricating a conformally metal-coated glass capillary array. The method of fabrication includes an ALD process form a thin conformal Pt film. Because the ALD process is extremely slow and not suitable for micron thick films, a micron thick gold film is added by electroplating.

ALD is a self-limiting, gas-phase growth technique capable of depositing ultrathin and conformal metal and metal oxide films on high aspect ratio substrates. The growth of ALD films occurs through sequential surface reactions that typically lead to a layer-by-layer growth mechanism when enough chemically active species exist on the initial substrate surface. The surface reactions can be thermally driven using elevated reaction temperatures or assisted by a plasma that generates reactive species to drive the surface reactions. Pt ALD on metal oxides does not typically result in the layer-by-layer growth mechanism. Rather, Pt ALD leads to the growth of Pt nanoparticles as described by island-like growth. Furthermore, noble metals by the ALD process suffer from poor nucleation due to the difference in surface energy between the substrate and metals, which can influence the growth characteristics. This can lead to non-continuous Pt coating. To improve Pt ALD film growth, an adhesion layers is deposited by ALD. Examples of acceptable adhesion layers include titanium and aluminum oxides. Both Al₂O₃ and TiO₂ improve Pt adhesion and film conformity. In an embodiment of the invention, an adhesion layer including TiO₂ provides more homogenous electroplating results than an adhesion layer including Al₂O₃.

Platinum Atomic Layer Deposition

Platinum ALD is employed according to an embodiment of the instant invention, to provide continuous Pt coverage along the GCA. Pt ALD thin films are versatile due to their excellent functional properties, such as low resistivity, high work function, the ability to catalyze chemical reactions, high thermal stability, corrosion resistance, and oxidation resistance. Pt thin films prepared by the ALD process have been reported using well-known Pt precursors: MeCpPtMe₃, Trimethyl-(methylcyclopentadienyl)-platinum(IV). In an embodiment of the instant invention, the Pt ALD growth rate is extremely slow with 0.48 Å/cycle.

Electroless Nickel

Because the Pt ALD is too slow to deposit thick films and because a good conductor for the electroplating is needed, a couple of hundreds nm nickel layer is added by electroless nickel plating. Electroless nickel plating is a process for depositing a nickel alloy from aqueous solutions onto a substrate without the use of electric current. It differs, therefore, from electroplating, which depends on an external source of direct current to reduce nickel ions in the electrolyte to nickel metal on the substrate. Electroless nickel plating is a chemical process, which reduces nickel ions in solution to nickel metal by chemical reduction. A common reducing agent used is sodium hypophosphite. Normally, a tin-palladium seeds act as a substrate catalyst, initiating metal deposition. The ALD Pt, for example, serves as a catalyst for electroless nickel. A continuous Ni side wall coating is added.

Electroless nickel deposition, according to an embodiment of the instant invention, starts with an activation process. Illustrative conditions according to an embodiment of the invention for a Pd activation include the following. Each activation step starts with an alkaline preclean/etch step (10-15 minutes, 70 C). For tin chloride solutions, concentrations of 0.1-0.5 mg/mL and a pH of 1.5 were preferred; for palladium chloride, 0.5-2 mg/mL concentration and pH<3. Silver nitrate solutions were 1 mg/mL. Tin chloride and silver nitrate solutions should be made immediately before use and not used more than once.

Electroplating Copper

Because gold plating solution is expensive, in an embodiment of the instant invention, copper plating is used to optimize the electroplating setup. Furthermore, copper is widely used to coat and fill high-aspect ratio holes. In an embodiment of the instant invention, pulsed current conditions are provided. DC (direct current) is problematic for continuous coating high-aspect-ratio holes. The electrolyte is a standard Cu plating solution manufactured by 3D Nano Systems, a conventional CuSO₄ electrolyte containing several standard additives (e.g., surfactants, levelers and accelerators). One of ordinary skill in the art will readily appreciate that alternative embodiments of the invention include different plated copper with different thicknesses inside a GCA.

Electroplating Gold

In another embodiment of the instant invention, pulsed electroplating conditions for the gold (Temperature of 60 C, Current Density of 10 mA/cm²) are provided. The plating solution is cyanide based “SG-20” from Transene Company Inc., electroplates gold alloy containing 0.5% Sb.

Silanization Process

In another embodiment of the instant invention, the Pt ALD provides the catalyst for the electroless nickel deposition. A silanization process resulted in siloxane (functional group in organosilicon) on the GCAs. The silanized GCA can be “activated” with Pd; and the Pd acts as catalyst for electroless Ni deposition. In other words, in another embodiment of the invention, the ALD process is replaced with a silanization (e.g., done in vacuum oven or in solution) and Pd activation. The Pd is the catalyst for the electroless Ni deposition.

For example, according to an embodiment of the instant invention includes the following silanization steps in solution:

(i) NaOH clean/etch, thorough rinse and vacuum oven dry.

(ii) Immersion in 5% solution of 3-aminopropyltrieth oxysilane in ethanol, rinse and oven dry for at least 20 minutes.

(iii) Immersion in acidic solution of palladium (II) chloride, thorough rinse.

Silanization steps under vacuum are done by placing the silanizing agent with the GCA in a standard vacuum desiccator. This forms a monolayer of silanes on the walls of the GCAs. The process, for example, takes˜ 30 min at 70° C. and overnight at room temperature.

Cycling Electroless Depositions

In another embodiment of the instant invention, immersion gold is employed.

Immersion gold is an electroless plating method, wherein Au replaces the Ni and forms a conformal coating. Since it's a replacement reaction, immersion gold stops at a certain thickness. Cycling electroless Ni (e.g., via a RTM process for “Room Temperature Metallizing For Alumina” by Transene Company, Inc.) and immersion gold builds up the needed wall coating thickness; this would replace the electroplating step mentioned in alternative embodiments discussed above.

Regarding electroless metal deposition described above, examples of acceptable electroless metals electroless Ni, Cu, Co, Ni, Fe, Ag, Sn, Au, Pt, Pd and their alloys.

Regarding electroplating described above, examples of acceptable plating conditions include pulsed voltage and direct-current electroplating as well as various current/voltage profiles and electrolyte compositions.

Regarding second metal electroplating described above, examples of acceptable electroplating first metals include Cu electroplating and Au electroplating. One of ordinary skill in the art will readily appreciate that alternative second metals that can be electroplated or alloys thereof are appropriate for alternative embodiments of the invention.

Regarding electroless metallization catalysts described above, examples of acceptable Catalysts include ALD Pt, ALD Pd (from RTM processes) and other standard catalytic materials.

Although a particular feature of the disclosure may have been illustrated and/or described with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising”.

As used herein, the singular forms “a”, “an,” and “the” do not preclude plural referents, unless the content clearly dictates otherwise.

As used herein, the term “and/or” includes any and all combinations of one or more of the associated listed items.

As used herein, the term “about” when used in conjunction with a stated numerical value or range denotes somewhat more or somewhat less than the stated value or range, to within a range of ±10% of that stated.

All documents mentioned herein are hereby incorporated by reference for the purpose of disclosing and describing the particular materials and methodologies for which the document was cited.

Although the present invention has been described in connection with preferred embodiments thereof, it will be appreciated by those skilled in the art that additions, deletions, modifications, and substitutions not specifically described may be made without departing from the spirit and scope of the invention. Terminology used herein should not be construed as being “means-plus-function” language unless the term “means” is expressly used in association therewith.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

These and other implementations are within the scope of the following claims.

1. A method comprising:
providing a glass capillary array, the glass capillary array comprising a plurality of glass capillary array walls, the plurality of glass capillary array walls defining a plurality of holes, the plurality of holes comprising a plurality of hole peripheries;
providing an electroless metallization catalyst around the plurality of hole peripheries;
electroless plating a first metal on the plurality of glass capillary array walls using the electroless metallization catalyst; and
one of: electroplating a second metal on the electroless-plated, first metal and electroless plating the second metal on the electroless-plated, first metal.

2. The method according to claim 1, wherein the electroless metallization catalyst comprises a nickel catalyst,
wherein said first metal comprises nickel,
wherein said electroless plating a first metal on the plurality of glass capillary array walls using the electroless metallization catalyst comprises electroless nickel plating the plurality of glass capillary array walls using the nickel catalyst.

3. The method according to claim 1, wherein the electroless metallization catalyst comprises a copper catalyst,
wherein said first metal comprises copper,
wherein said electroless plating a first metal on the plurality of glass capillary array walls using the electroless metallization catalyst comprises electroless copper plating the plurality of glass capillary array walls using the copper catalyst.

4. The method according to claim 1, wherein each hole of the plurality of holes comprises an aspect ratio greater than 40:1.

5. The method according to claim 1, wherein said providing an electroless metallization catalyst around the plurality of hole peripheries comprises:
coating the plurality of glass capillary array walls with a noble metal by atomic layer deposition.

6. The method according to claim 5, further comprising:
providing a wetting layer on the plurality of array walls, prior to said coating the plurality of array walls with platinum by atomic layer deposition.

7. The method according to claim 6, wherein the wetting layer comprises one of Al₂O₃ and TiO₂.

8. The method according to claim 1, wherein said providing an electroless metallization catalyst on the plurality of hole peripheries comprises:
silanizing the plurality of glass capillary array walls; and
providing palladium(II) chloride on the silanized plurality of glass capillary array walls.

9. The method according to claim 1, wherein the second metal comprises one of a noble metal and a noble metal alloy.

10. The method according to claim 9, wherein the noble metal comprises one of copper, gold, silver, and platinum.

11. A glass capillary array comprising:
a plurality of glass capillary array walls, the plurality of glass capillary array walls defining a plurality of holes, the plurality of holes comprising a plurality of hole peripheries;
an electroless metallization catalyst on the plurality of glass capillary array walls around the plurality of hole peripheries;
an electroless-plated first metal on the electroless metallization catalyst; and
one of: an electroplated second metal on the electroless-plated first metal, and an electroless-plated second metal on the electroless-plated first metal.

12. The glass capillary array according to claim 11, wherein said electroless metallization catalyst comprises a nickel catalyst,
wherein said electroless-plated first metal comprises electroless-plated nickel.

13. The glass capillary array according to claim 12, wherein said nickel catalyst comprises platinum.

14. The glass capillary array according to claim 12, wherein said nickel catalyst comprises silane and palladium.

15. The glass capillary array according to claim 11, wherein said electroless metallization catalyst comprises a copper catalyst,
wherein said electroless-plated first metal comprises electroless-plated copper.

16. The glass capillary array according to claim 11, wherein said first metal comprises a noble metal,
wherein said second metal comprises one of the noble metal and a noble metal alloy.

17. The glass capillary array according to claim 16, wherein said noble metal comprises one of copper, gold, silver, and platinum.

18. The glass capillary array according to claim 11, wherein each hole of the plurality of holes comprises an aspect ratio greater than 40:1.

19. The glass capillary array according to claim 11, further comprising:
a wetting layer located between said plurality of glass capillary array walls and said electroless metallization catalyst.

20. The glass capillary array according to claim 19, wherein said wetting layer comprises one of Al₂O₃ and TiO₂
